(19) United States
(12) Patent Application Publication
(10) Pub. No.: US 2026/0221316 A1
(43) Pub. Date: Jul. 30, 2026

(54) CONDUCTING MEMBER AND WIRE

(71) Applicant: Yazaki Corporation, Tokyo (JP)

(72) Inventor: Kazuyoshi Kagami, Shizuoka (JP)

(21) Appl. No.: 19/041,409

(22) Filed: Jan. 30, 2025

(51) Int. Cl. H01B 7/42; H10N 10/10

(52) U.S. Cl. CPC H01B 7/423; H01B 7/426; H10N 10/10

(57) ABSTRACT

A conducting member includes: a conductor; a thermoelectric element placed on the conductor with a heat absorbing surface in contact with a heat generation surface of the conductor and a heat radiation surface facing outside air, the thermoelectric element generating power by a temperature difference between the heat absorbing surface and the heat radiation surface; and a refrigerant flowing unit configured to allow a refrigerant to flow by being driven by the power generated by the thermoelectric element and to cool the conductor by a flow of the refrigerant.

### BACKGROUND

### 1. Field of the Invention

The present disclosure relates to a conducting member and a wire capable of reducing a temperature rise of a conductor when a large current flows.

### 2. Description of the Related Art

A wire or a bus bar, which is used as a wiring member for allowing a current of a drive system of an electric vehicle to flow, needs to allow a large current to flow through a conductor as compared with a case where a wire or a bus bar is used as a wiring member for distributing a current from a low-voltage power supply to an auxiliary device or the like on a vehicle, and thus heat generation of the conductor increases.

In the bus bar or the wire in which such a large current flows, a countermeasure against heat generation of a conductor itself which is a conducting member is desired.

In the related art, there has been known that a cooling fan is driven using a temperature difference power generation function (Seebeck effect) by a thermoelectric element (for example, a Peltier element) to cool a space to be cooled (for example, see JP2008-28878A).

However, in JP2008-28878A, a wiring member for a vehicle such as a bus bar or a wire is not a cooling target, and a configuration for cooling the bus bar or the wire is hardly sufficiently studied.

### SUMMARY

The present disclosure has been made in view of the above-described circumstances, and an object of the present disclosure is to provide a conducting member and a wire capable of preventing a temperature rise of a conductor using heat generated by the conductor itself without using external power.

In order to achieve the above object, a conducting member and a wire according to the present disclosure are characterized as follows.

According to an aspect of the present disclosure, there is provided a conducting member including: a conductor; a thermoelectric element placed on the conductor with a heat absorbing surface in contact with a heat generation surface of the conductor and a heat radiation surface facing outside air, the thermoelectric element generating power by a temperature difference between the heat absorbing surface and the heat radiation surface; and a refrigerant flowing unit configured to allow a refrigerant to flow by being driven by the power generated by the thermoelectric element and to cool the conductor by a flow of the refrigerant.

According to another aspect of the present disclosure, there is provided a wire comprising the conducting member.

According to the present disclosure, it is possible to provide a conducting member and a wire capable of preventing a temperature rise of a conductor without requiring external power for cooling.

The present disclosure has been briefly described above. Details of the present disclosure can be clarified by reading modes (hereinafter, referred to as “embodiments”) for carrying out the invention to be described below with reference to the accompanying drawings.

### BRIEF DESCRIPTION OF THE DRAWINGS

The present disclosure will become more fully understood from the detailed description given hereinbelow and the accompanying drawing which is given by way of illustration only, and thus is not limitative of the present disclosure and wherein:

FIG. 1 is a longitudinal sectional view showing a schematic configuration of a first embodiment;

FIG. 2 is a longitudinal sectional view and a transverse sectional view showing a schematic configuration of a second embodiment;

FIG. 3 is a longitudinal sectional view showing a schematic configuration of a third embodiment; and

FIG. 4 is a longitudinal sectional view showing a schematic configuration of a fourth embodiment.

### DESCRIPTION OF EMBODIMENTS

A specific embodiment of the present disclosure will be described below with reference to the drawings.

### First Embodiment

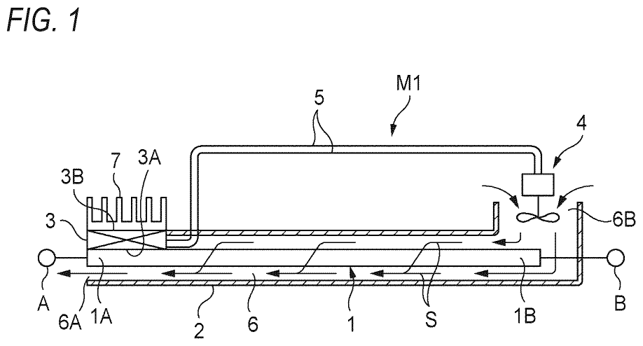

FIG. 1 is a longitudinal sectional view showing a schematic configuration of a conducting member M1 according to a first embodiment.

The conducting member M1 shown in FIG. 1 is wired in a vehicle, for example. In a case where a bus bar 1 is used as a conducting member for allowing a large current to flow between two points, point A and point B, for example, between a high-voltage battery and a drive device of an electric vehicle, heat generation due to its own electric resistance increases as compared with a case where a current flows between a low-voltage battery and an auxiliary device.

Therefore, a thermoelectric element 3 having a temperature difference power generation function by the Seebeck effect is placed on a heat generation surface of the bus bar 1. The thermoelectric element 3 includes, for example, a Peltier element. The thermoelectric element 3 is disposed such that a heat absorbing surface 3A is in close contact with the heat generation surface of the bus bar 1 and a heat radiation surface 3B faces the outside air. On the heat radiation surface 3B of the thermoelectric element 3, a heat sink 7 is disposed with its heat absorbing surface in close contact with the heat radiation surface 3B. Accordingly, heat radiation of the heat radiation surface 3B of the thermoelectric element 3 is promoted. Since the thermoelectric element 3 is disposed on the heat generation surface of the bus bar 1 in this manner, the thermoelectric element 3 generates power due to a temperature difference between the heat absorbing surface 3A and the heat radiation surface 3B, and supplies the generated power to the outside via a wiring 5.

A front end of the wiring 5 is connected to a motor of a cooling fan 4. The power generated by the thermoelectric element is supplied to the motor of the cooling fan 4 via the wiring 5. The cooling fan 4 generates cooling air S to cool the bus bar 1.

The bus bar 1 is provided with an exterior member 2 that covers an outer periphery of the bus bar 1, and the cooling air S flows through a flow path 6 secured between the exterior member 2 and the bus bar 1, thereby cooling the bus bar 1. The flow path 6 between the exterior member 2 and the bus bar 1 is basically closed except for an inlet 6B and an outlet 6A, and outside air (air) serving as the cooling air S is taken into the flow path 6 from the inlet 6B in which the cooling fan 4 is disposed, and flows from the inlet 6B side toward the outlet 6A. The outlet 6A is an exhaust port for cooling air that has absorbed heat, and is preferably provided at an end portion of the bus bar 1, but an installation location is not particularly limited. Examples of the exterior member 2 include a corrugated tube, a tubular cover, and a covering member.

Due to the flow of the cooling air S described above, the temperature of the bus bar 1 is lower at an end portion 1B on the inlet 6B side and higher at an end portion 1A on the outlet 6A side. Therefore, the thermoelectric element 3 is disposed at a position close to the end portion 1A on a high temperature side and away from the cooling fan 4. The bus bar 1 is not limited to a linear shape, and various shapes can be adopted, but it is desirable that a position at which the thermoelectric element 3 is disposed and a position at which the outside air is taken in by the cooling fan 4 (the inlet 6B of the flow path 6) are separated as much as possible. In this embodiment, a refrigerant is air, and a refrigerant flowing unit is the cooling fan 4.

According to the above configuration, power is generated in the thermoelectric element 3 using the heat generated by the bus bar 1 itself which is a main body of the conducting material, and the cooling fan 4 is driven using the generated power to cool the bus bar 1. Therefore, the temperature rise of the bus bar 1 can be prevented without requiring external power for cooling. Further, since a cooling capacity is automatically controlled according to a heat generation amount of the bus bar 1, it is not necessary to provide a complicated control device.

By having such a cooling function, it is possible to use the bus bar 1 having a smaller cross-sectional area than in a case where the bus bar 1 does not have the cooling function, and it is possible to achieve weight reduction, cost reduction, and reduction in environmental load.

According to the present embodiment, since the heat sink 7 is disposed on the heat radiation surface 3B of the thermoelectric element 3, a temperature difference between the heat absorbing surface 3A and the heat radiation surface 3B of the thermoelectric element 3 can be made large, and a power generation capacity of the thermoelectric element 3 can be increased. Further, since the cooling fan 4 is driven using the power generated by the thermoelectric element 3 to air-cool the bus bar 1, the temperature rise of the bus bar 1 can be prevented with a simple configuration. Further, since the cooling air S flows through the flow path 6 secured between the exterior member 2 and the bus bar 1, the bus bar 1 can be efficiently cooled.

### Second Embodiment

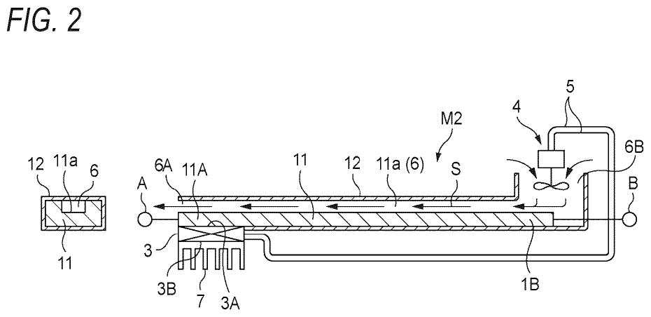

FIG. 2 is a longitudinal sectional view and a transverse sectional view showing a schematic configuration of a conducting member M2 in a second embodiment.

In the conducting member M2 of the second embodiment shown in FIG. 2, a recessed groove 11a is provided on an outer surface of a bus bar (conductor) 11, and the flow path 6 through which the cooling air S flows is secured between the recessed groove 11a and a covering member (exterior member) 12 covering an outer periphery of the bus bar 11. Since the recessed groove 11a is provided on the outer surface of the bus bar 11, the covering member 12 can be provided in close contact with the outer surface of the bus bar 11. Since other configurations are the same as those of the first embodiment, the same components are denoted by the same reference numerals, and description thereof will be omitted.

In the conducting member M2, the cooling air S generated by the cooling fan 4 flows from the inlet 6B side to the outlet 6A (exhaust port) side of the flow path 6 to cool the bus bar 11. Therefore, an end portion 11B of the bus bar 11 on the inlet 6B side is on a low temperature side, and an end portion 11A of the bus bar 11 on the outlet 6A side is on the high temperature side. Other operations and effects are the same as those of the first embodiment.

### Third Embodiment

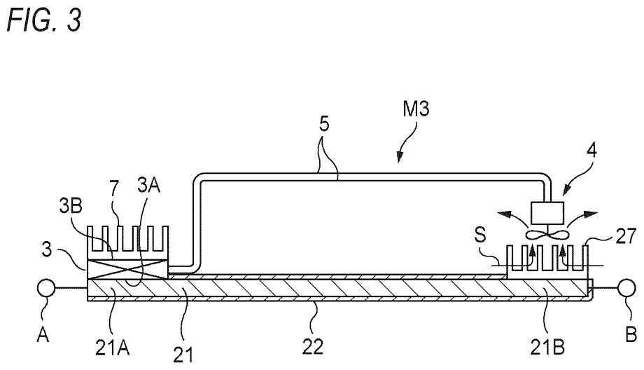

FIG. 3 is a longitudinal sectional view showing a schematic configuration of a conducting member M3 in a third embodiment.

In the conducting member M3 of the third embodiment shown in FIG. 3, instead of securing the flow path through which the cooling air S flows along a bus bar 21, the cooling fan 4 that cools the bus bar 21 at a position away from the thermoelectric element 3 is disposed at a position away from the thermoelectric element 3. The cooling fan 4 is disposed to locally cool a part of the bus bar 21, like a cooling structure of a CPU of a computer. That is, a heat sink 27 that absorbs the heat of the bus bar 21 and releases the heat to the outside air is disposed between the bus bar 21 and the cooling fan 4, and the cooling fan 4 is provided so as to circulate the cooling air S through a cooling fin of the heat sink 27. The arrangement of the thermoelectric element 3 is the same as that of the first embodiment. Since an exterior member 22 does not secure a flow path between the exterior member 22 and the bus bar 21, any material may be used.

In the conducting member M3, like a cooling structure of the CPU of the computer, the air of the cooling fan 4 is applied to the cooling fin of the heat sink 27, so that a part of the bus bar 21 can be efficiently cooled. By locally cooling a part of the bus bar 21, it is also possible to prevent a temperature rise of other portions of the bus bar 21 by using heat conduction. Further, since the thermoelectric element 3 and the cooling fan 4 are separated from each other, it is possible to obtain a cooling effect of the bus bar 21 while maintaining power generation efficiency of the thermoelectric element 3 at the maximum. Therefore, one end 21B of the bus bar 21 on which the cooling fan 4 is disposed is on the low temperature side, and the other end 21A of the bus bar 21 on which the thermoelectric element 3 is disposed is on the high temperature side.

### Fourth Embodiment

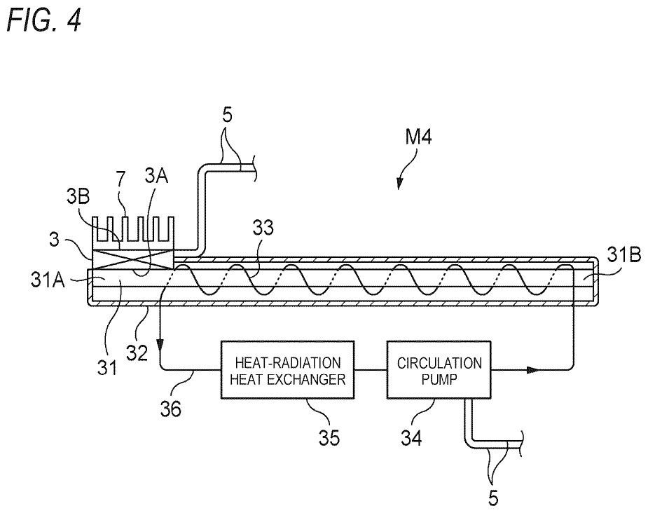

FIG. 4 is a longitudinal sectional view showing a schematic configuration of a conducting member M4 in a fourth embodiment.

In the conducting member M4 of the fourth embodiment shown in FIG. 4, a liquid such as water is used as the refrigerant. Therefore, a water-cooling jacket 33 is provided along an outer periphery of a bus bar 31. In a refrigerant circulation path 36 including the water-cooling jacket 33, a heat-radiation heat exchanger 35 that releases heat absorbed by cooling water flowing through the water-cooling jacket 33 to the outside and a circulation pump 34 that circulates the cooling water are provided.

The power generated by the thermoelectric element 3 is used as the power for driving the circulation pump 34. Since a low temperature side 31B and a high temperature side 31A of the bus bar 31 are determined by the arrangement of the water-cooling jacket 33, the thermoelectric element 3 is disposed at a position close to the high temperature side 31A. Also in this case, the exterior member 32 may be disposed so as not to interfere with the installation of the water-cooling jacket 33.

According to the fourth embodiment, since the bus bar 31 is water-cooled using the power generated by the thermoelectric element 3, a high cooling effect can be achieved.

The present disclosure is not limited to the embodiments described above, and can be appropriately modified, improved, or the like. In addition, materials, shapes, sizes, numbers, arrangement positions, or the like of components in the embodiments described above are freely selected and are not limited as long as the present disclosure can be implemented.

For example, in the first embodiment and the second embodiment, by wiring the wire using the conducting member M1 or the conducting member M2 in the vehicle such that the outlet 6A serving as the exhaust port is located at a position higher than the inlet 6B, the cooling air S heated by absorbing the heat of the bus bar 1 in the flow path 6 easily and naturally flows in a direction toward the outlet 6A.

As an example, the conducting member in each of the embodiments described above may constitute a part of a wire having connectors at both ends.

Here, characteristics of a conducting member and a wire according to the above embodiments of the present disclosure will be briefly summarized and listed in the following to [8]. [1] A conducting member (M1, M2, M3, M4) including:
a conductor (1, 11,21, 31);
a thermoelectric element (3) placed on the conductor with a heat absorbing surface (3A) in contact with a heat generation surface of the conductor and a heat radiation surface (3B) facing outside air, the thermoelectric element generating power by a temperature difference between the heat absorbing surface and the heat radiation surface; and
a refrigerant flowing unit (4, 34) configured to allow a refrigerant to flow by being driven by the power generated by the thermoelectric element and to cool the conductor by a flow of the refrigerant.

According to the conducting member having the above configuration [1], the power is generated in the thermoelectric element (3) using the heat generated by the conductor (1, 11,21, 31) itself which is a main body of the conducting material, and the refrigerant is caused to flow using the generated power to cool the conductor. Therefore, a temperature rise of the conductor can be prevented without requiring external power for cooling. In addition, since a cooling capacity is automatically controlled according to a heat generation amount of the conductor, it is not necessary to provide a complicated control component.

[2] The conducting member (M1, M2, M3, M4) according to the above [1], in which
a heat sink (7) is disposed on the heat radiation surface (3B) of the thermoelectric element.

According to the conducting member having the above configuration [2], since the heat sink (7) is disposed on the heat radiation surface of the thermoelectric element, the temperature difference between the heat absorbing surface and the heat radiation surface of the thermoelectric element can be made large, and a power generation capacity of the thermoelectric element can be increased.

[3] The conducting member (M1, M2, M3) according to the above [1], in which
the refrigerant is air, and the refrigerant flowing unit is a cooling fan (4) that circulates cooling air.

According to the conducting member having the above configuration [3], since the cooling fan (4) is driven using the power generated by the thermoelectric element to air-cool the conductor, the temperature rise of the conductor can be prevented with a simple configuration.

[4] The conducting member (M1, M2) according to the above [3], further including:
an exterior member (2, 12) covering the conductor, in which
a flow path (6) through which the cooling air flows is formed between the conductor and the exterior member.

According to the conducting member having the above configuration [4], since the cooling air flows through the flow path (6) secured between the exterior member and the conductor, the conductor can be efficiently cooled.

[5] The conducting member (M3) according to the above [3], in which
a cooling fan (4) that cools the conductor (21) at a position away from the thermoelectric element is disposed at a position away from the thermoelectric element (3).

According to the conducting member having the above configuration [5], like a cooling structure of the CPU of the computer, by locally cooling a part of the conductor by the cooling fan (4), it is also possible to prevent a temperature rise of other portions of the conductor by using heat conduction. Here, since the thermoelectric element and the cooling fan are separated from each other, it is possible to obtain a cooling effect of the conductor while maintaining power generation efficiency of the thermoelectric element at the maximum.

[6] The conducting member (M3) according to the above [5], in which
a heat sink (27) that absorbs heat of the conductor and releases the heat to the outside air is disposed between the conductor (21) and the cooling fan (4), and the cooling fan (4) is provided so as to circulate the cooling air through a cooling fin of the heat sink.

According to the conducting member having the above configuration [6], since the air of the cooling fan (4) is applied to the cooling fin of the heat sink (27) like the cooling structure of the CPU of the computer, the conductor can be efficiently cooled.

[7] The conducting member (M4) according to the above[1], in which
the conductor (31) is provided with a water-cooling jacket (33) that cools the conductor,
in a refrigerant circulation path (36) of the water-cooling jacket, a heat-radiation heat exchanger (35) that releases heat absorbed by cooling water flowing through the water-cooling jacket to outside and a circulation pump (34) that circulates the cooling water are provided, and
the circulation pump (34) constitutes the refrigerant flowing unit, and the cooling water constitutes the refrigerant.

According to the conducting member having the above configuration [7], since the conductor is water-cooled using the power generated by the thermoelectric element, a high cooling effect can be achieved.

[8] A wire including the conducting member according to any one of the above [1] to [7].

According to the wire having the above configuration [8], even when the wire is wired in the vehicle and a large current of a drive system flows, a temperature rise of the conducting member constituting the wire can be prevented.

1. A conducting member comprising:
a conductor;
a thermoelectric element placed on the conductor with a heat absorbing surface in contact with a heat generation surface of the conductor and a heat radiation surface facing outside air, the thermoelectric element generating power by a temperature difference between the heat absorbing surface and the heat radiation surface; and
a refrigerant flowing unit configured to allow a refrigerant to flow by being driven by the power generated by the thermoelectric element and to cool the conductor by a flow of the refrigerant.

2. The conducting member according to claim 1, wherein
a heat sink is disposed on the heat radiation surface of the thermoelectric element.

3. The conducting member according to claim 1, wherein
the refrigerant is air, and the refrigerant flowing unit is a cooling fan that circulates cooling air.

4. The conducting member according to claim 3, further comprising:
an exterior member covering the conductor, wherein
a flow path through which the cooling air flows is formed between the conductor and the exterior member.

5. The conducting member according to claim 3, wherein
a cooling fan that cools the conductor at a position away from the thermoelectric element is disposed at a position away from the thermoelectric element.

6. The conducting member according to claim 5, wherein
a heat sink that absorbs heat of the conductor and releases the heat to the outside air is disposed between the conductor and the cooling fan, and the cooling fan is provided so as to circulate the cooling air through a cooling fin of the heat sink.

7. The conducting member according to claim 1, wherein
the conductor is provided with a water-cooling jacket that cools the conductor,
in a refrigerant circulation path of the water-cooling jacket, a heat-radiation heat exchanger that releases heat absorbed by cooling water flowing through the water-cooling jacket to outside and a circulation pump that circulates the cooling water are provided, and
the circulation pump constitutes the refrigerant flowing unit, and the cooling water constitutes the refrigerant.

8. A wire comprising the conducting member according to claim 1.
